(19) United States
(12) Patent Application Publication
(10) Pub. No.: US 2021/0345477 A1
(43) Pub. Date: Nov. 4, 2021

(54) SEMICONDUCTOR LASER ACCELERATOR AND LASER ACCELERATION UNIT THEREOF

(71) Applicant: Huizhou University, Huizhou (CN)

(72) Inventors: Hongxiang Lin, Huizhou (CN); Tong Liu, Huizhou (CN); Han Cui, Huizhou (CN); Zhaoquan Cai, Huizhou (CN); Xiaohui Wei, Huizhou (CN)

(21) Appl. No.: 17/368,103

(22) Filed: Jul. 6, 2021

Related U.S. Application Data
(63) Continuation of application No. PCT/CN2019/117010, filed on Nov. 11, 2019.

(30) Foreign Application Priority Data
Jan. 8, 2019 (CN) 201910015263.2

(51) Int. Cl. H05H 15/00; H01S 5/042; H01S 5/026; H01S 5/12; H01S 5/062; H01S 5/02257; H01S 5/323

(52) U.S. Cl. CPC H05H 15/00; H01S 5/04256; H01S 5/026; H01S 5/32391; H01S 5/0427; H01S 5/06246; H01S 5/02257; H01S 5/12

(57) ABSTRACT

A semiconductor laser accelerator includes several laser acceleration units linked in a cascade manner, and a controller configured to control excitation current supplied to the laser acceleration units. Each laser acceleration unit includes electrodes, an active layer, a first waveguide layer defining one acceleration channel, a second waveguide layer, and a reflecting layer. One or two optical gratings are formed on one or two sides of the acceleration channel to serve as an accelerating area. The semiconductor laser accelerator exhibits a higher acceleration gradient and a smaller structure while not requiring a complex external optical system. In addition, an optical field is controlled by external excitation current, the matching control of an electron beam and an optical field phase can be realized, and the problem of a phase slip can be solved by means of cascade expansion.

### CROSS-REFERENCE TO RELATED APPLICATIONS

The present application is a continuation of PCT application No. PCT/CN2019/117010, filed on Nov. 11, 2019, which designates United States and claims priority of China Patent Application No. 201910015263.2, filed on Jan. 8, 2019 which is incorporated herein by reference.

### BACKGROUND OF THE INVENTION

### 1. Field of the Invention

The present invention relates to an accelerator and a laser acceleration unit, in particular to a semiconductor laser accelerator and a laser acceleration unit.

### 2. Description of Related Art

With the development of modern science and technology, people have a more and more in-depth understanding of material composition. As exploring different levels of the material world needs different detection tools, a particle accelerator is one of the important tools for the human to explore the micro-world. Since the first particle accelerator in the world came into being in the 19th century, more than 200 large accelerator devices have been built in countries over the world, making exhilarating achievements in life science, chemical materials, high energy physics, national defense technology, medical and health, and like fields. For example, the first of the ten annual advances in the 2012 journal of the Science Magazine in the United States is the important outcome of using a large hadron collider (LHC) to observe Higgs particles. Although the LHC has excellent performance, it is also expensive to build. The total project funding exceeds 7 billion U.S. dollars. It has the world's longest perimeter and is the most expensive particle accelerator. This is also a common problem with accelerator devices, such as other accelerator devices that produce hard X-rays, which typically have a total budget of over 1 billion U.S. Dollars. The sizes of the devices are measured in kilometers. The large size and high construction cost prevent the accelerator from being applied to a wider range of basic science and industry. Therefore, whether in scientific research or the field of civil accelerators, the miniaturization and low cost of accelerators are important directions of their development.

At present, the two most promising accelerator miniaturization technology directions recognized in the world are as follows: medium laser accelerator and plasma accelerator. Both accelerator technologies enable acceleration gradients of GeV/m or even higher. Compared with the traditional RF accelerator, the medium laser accelerator has two differences, one being the difference in power sources. RF accelerators usually employ klystrons, transmitters as the power source of an accelerator, while medium laser accelerators employ high-power short-pulse lasers to directly radiate optical gratings (or photonic crystals, etc.). The other difference is that the acceleration structure uses different materials. RF accelerators typically employ oxygen-free copper or other metallic materials, while medium accelerators typically employ optical medium materials. Because the laser apparatus is used as a power source for the accelerator, the laser apparatus is small in volume and low in cost compared with the klystron, and the medium material has a higher breakdown threshold compared with the metal material so that a higher acceleration gradient can be generated. In 2013, Nature reported the latest research results of the medium laser accelerator of the Stanford University. A high-gradient accelerating electric field is formed inside the optical grating by irradiating two laser beams on the surface of the optical grating medium, and the accelerating gradient reaches 250 MeV/m which is far higher than the accelerating gradient of 30 MeV/m of the conventional accelerator at present. It is also pointed out that the electron acceleration phase and the electric field phase of the medium laser accelerator are different, which results in phase slip, in the accelerating area of non-relativistic electrons.

### BRIEF DESCRIPTION OF THE SEVERAL VIEWS OF THE DRAWING(S)

The foregoing and other exemplary purposes, aspects and advantages of the present invention will be better understood in principle from the following detailed description of one or more exemplary embodiments of the invention with reference to the drawings, in which:

FIG. 1 is a schematic view illustrating a structure of a semiconductor laser accelerator according to an embodiment of the present invention.

FIG. 2 is a top cross-sectional view of a portion of a semiconductor laser acceleration unit according to an embodiment of the present invention.

FIG. 3 is an enlarged view of a portion B of FIG. 2.

FIG. 4 is a front cross-sectional view of a semiconductor laser acceleration unit according to an embodiment of the present invention.

FIG. 5 is a schematic perspective view of a portion of a semiconductor laser acceleration unit according to an embodiment of the present invention.

FIG. 6 is a simulation view of an electromagnetic field of an acceleration field of the semiconductor laser acceleration unit of FIG. 3.

FIG. 7 is an electron beam tracking result view of an electromagnetic field simulation software of a semiconductor laser acceleration unit according to an embodiment of the present invention.

FIG. 8 is a Fourier transform view of an electric field at a probe position.

FIG. 9 shows a deceleration effect (simulation software CST) view presented by 10 keV non-relativistic electrons due to phase slip when a long optical grating structure is used in the present invention.

FIG. 10 is a schematic view of a polarized light path in a Brewster window.

FIG. 11 is a relation graph of an acceleration gradient versus an optical grating length for a non-relativistic electron phase slip.

### DETAILED DESCRIPTION OF THE INVENTION

The invention will now be described in detail through several embodiments with reference to the accompanying drawings.

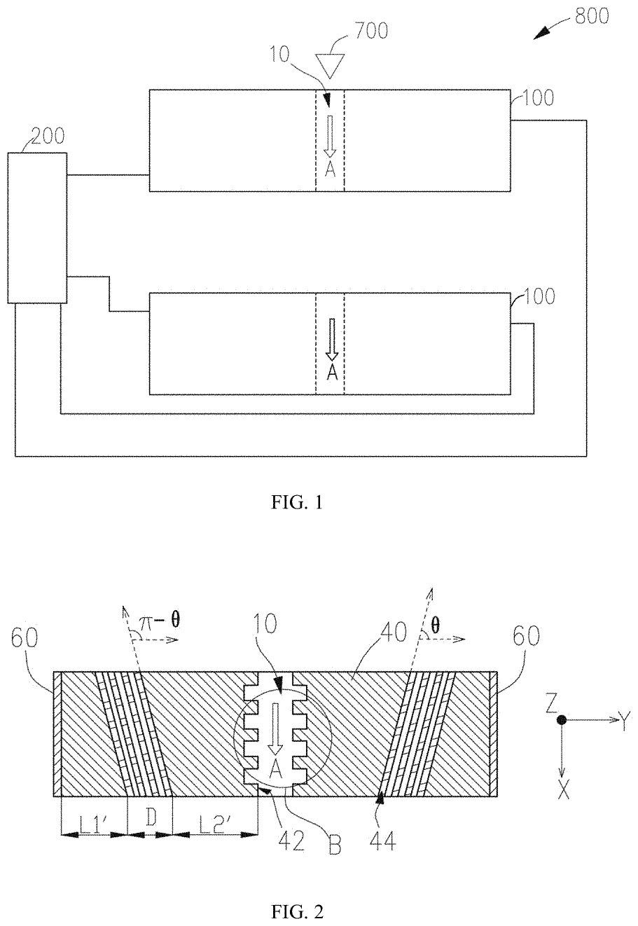

Referring to FIG. 1, a semiconductor laser accelerator 800 of the present invention is used to accelerate electrons emitted from a radiation source 700, and may include two or two more laser acceleration units 100 (only two of which are shown in FIG. 1 for convenience of comparison) and a controller 200 electrically connected to the laser acceleration units 100.

Each laser acceleration unit 100 defines an acceleration channel 10 (shown in dotted lines in FIG. 1) extending in a first direction A, and the laser acceleration units 100 are coupled in a cascade manner, so that the acceleration channels 10 of the laser acceleration units 100 are located in a straight line, end to end. A vacuum gap serving as a drift section exists between adjacent acceleration units, and a length of the drift section should be dozens or more times of the acceleration channel of a single acceleration unit. An illustrated length of the gap is not long enough in FIG. 1 for ease of viewing. Electrons emitted from the radiation source 700 are sequentially accelerated through the plurality of laser acceleration units 100.

The controller 200 is electrically connected with the electrodes of the plurality of laser acceleration units 100 respectively. The controller 200 can independently control a timing sequence and an amplitude of an excitation current of each acceleration unit, and in particular adjust a triggering time of the excitation current to realize the control and adjustment of a phase of an electromagnetic field in an accelerating area of the acceleration unit. It will be understandably that the semiconductor laser accelerator 800 may include a housing, and the controller may be located within the housing or external to the housing. The remaining components of the semiconductor laser accelerator 800 may be located within the housing and an inner space of the housing is preferred to be a vacuum state.

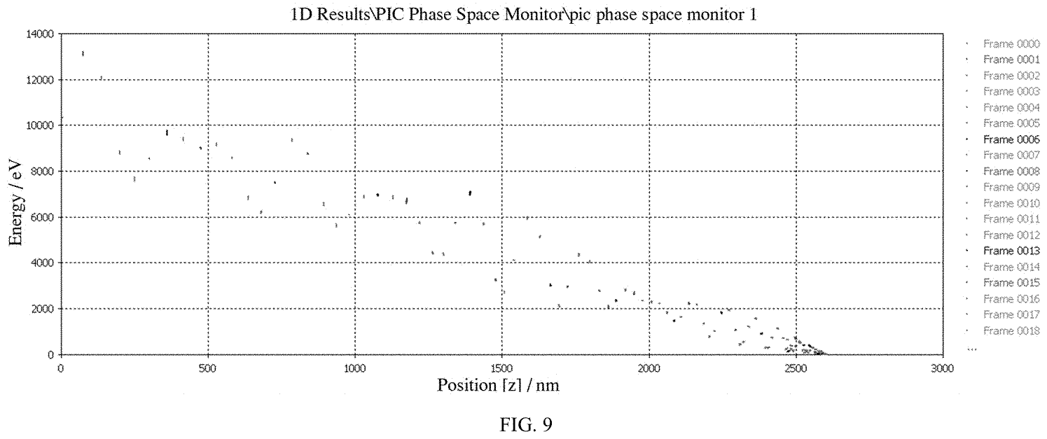

The acceleration structure of the semiconductor laser accelerator 800 can meet the acceleration requirements of relativistic electrons and non-relativistic electrons. For non-relativistic electrons, the electron displacement is gradually increased within a single time period in the acceleration process due to the lower speed of the non-relativistic electrons. The invention uses short optical gratings for acceleration, and provide different excitation currents to different laser acceleration units 100 so as to ensure that each section of the acceleration segment has a high acceleration gradient (the acceleration gradient of the shaded portion in FIG. 11 is high), therefore the deceleration effect in the phase slip area is effectively avoided (referring to FIG. 9), and electrons are accelerated more effectively.

The detailed structure of a single laser acceleration unit 100 is described in detail below. For convenience of description, a space rectangular coordinate system XYZ is defined and have an X-axis, a Y-axis and a Z-axis perpendicular with each other. The laser acceleration unit is located in an origin of the space rectangular coordinate system XYZ. Furthermore, a X-axis direction is defined to describe a direction that is parallel with the X-axis, a Y-axis direction is defined to describe a direction that is parallel with the Y-axis, and a Z-axis direction is defined to describe a direction that is parallel with the Z-axis. The above-mentioned first direction A is parallel to the X-axis direction. Electrons enter the channel 10 from a rear positon in the X-axis direction, and are emitted from the acceleration channel after being accelerated in a front position in the X-axis direction.

In a preferred embodiment, as shown in FIGS. 2 to 5, the laser acceleration unit 100 at least includes two electrodes 20 separately arranged in the Z-axis direction, an active layer 30 disposed between the electrodes 20, a first waveguide layer 40 located in front of the active layer 30 in the Z-axis direction, a second waveguide layer 50 located behind the active layer 30 in the Z-axis direction, and two reflecting layers 60 located in front of and behind the active layer 30, the first waveguide layer 40, and the second waveguide layer 50 in the Y-axis direction. That is, in the Z-axis direction, a first electrode 20, the first waveguide layer 40, the active layer 30, the second waveguide layer 50, and a second electrode 20 are sequentially arranged from front to back; the two reflecting layers 60 are arranged at two ends of the laser acceleration unit 100 in the Y-axis direction.

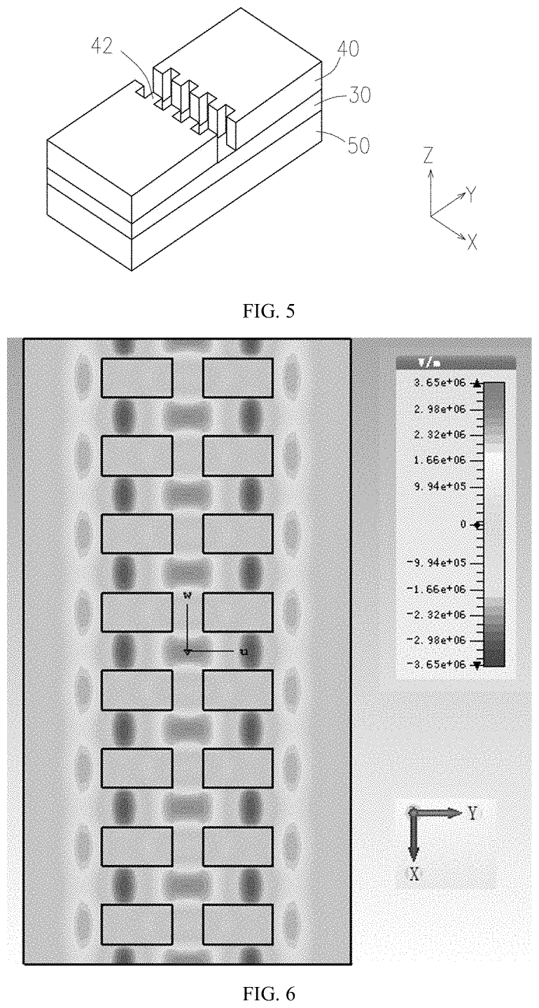

To facilitate distinguishing portions of the laser acceleration unit 100, FIG. 5 shows a perspective view of the active layer 30, the first waveguide layer 40, and the second waveguide layer 50 of the laser acceleration unit 100, omitting the electrode 20, the reflecting layer 60, and the Brewster windows 44 located within the first waveguide layer 40; and in FIG. 4, only a cross-sectional view of the laser acceleration unit 100 taken along a plane defined parallel to the Y-axis and Z-axis in FIG. 5 is shown, and only cross-sectional lines of the active layer 30, the reflecting layers 60, and the Brewster windows 44 are shown in order to prevent too many cross-sectional lines from affecting the observation, and the cross-sectional lines of the electrodes 20, the first waveguide layer 40, and the second waveguide layer 50 are omitted, and the part of the Brewster windows 44 which should be located inside the first waveguide layer 40 is shown by shading; a cross-sectional view of the first waveguide layer 40 of the laser acceleration unit 100 taken along a plane parallel to the plane defined by X-axis and Y-axis in FIG. 5 is shown in FIG. 2.

The active layer 30 has an active area 31. A main extension plane of the active layer 30 is parallel to the plane defined by X-axis and Y-axis. In the embodiment, the active layer 30 as a whole is composed of a semiconductor material such as, but not limited to, InGaAsP (Indium Gallium Arsenic Phosphorus) semiconductor material for generating laser when the electrodes are energized. Thus the whole active layer 30 serves as the active area 31. In other embodiments, the semiconductor material capable of emitting laser may be located only in the middle of the active layer 30, and the portions at the periphery may be a waveguide material, thus the active area 31 only exists in the middle of the active layer 30. The main extension planes of the first waveguide layer 40 and the second waveguide layer 50 are also parallel to the plane defined by X-axis and Y-axis. In the embodiment, the active layer 30, the first waveguide layer 40, and the second waveguide layer 50 are stacked into a cuboid structure having six faces parallel to the planes defined by the X-axis and Y-axis, the Y-axis and Z-axis, and the X-axis and Z-axis, respectively. The reflecting layers 60 are attached to two side surfaces of the cuboid structure located in the Y-axis direction so that the radiated lasers generated by the active area are coupled to the first waveguide layer and the second waveguide layer at a certain connecting rate, and the radiated lasers are reflected by the reflecting layers and return to form an optical resonator. The electrodes 20 may each have one or more metal layers, which may include, for example but without limitation, alloys of one or more of Ag, Au, Sn, Ti, Pt, Pd, Rh, and Ni. The reflecting layers 60 may include a high reflectivity film or be a high reflectivity coating, such as but not limited to, a metal layer having a Bragg mirror layer sequence or reflectivity.

It will be understandably that other functional layers may also be configured between the waveguide layers and the electrodes, such as, but not limited to, a passivation layer, an insulation layer, a growth substrate, etc.

In the present invention, the acceleration channel 10 is formed in the first waveguide layer 40, thus the first waveguide layer 40 is divided into two parts respectively located in a front positon and a rear position in the Y-axis direction. Two optical gratings 42 acting as accelerating areas are formed in the first waveguide layer 40 on both sides of the acceleration channel 10. The optical gratings 42 have slits extending in the Z-axis direction. The active area of the active layer 30 is exposed to the bottom of the acceleration channel 10, viewed from the front of the Z-axis direction. The optical gratings 42 may be formed in the first waveguide layer 40 by photolithography and wet etching. In order to meet the requirement of the electron acceleration phase, an optical grating constant of the optical gratings 42 is the laser wavelength, namely, the following formula is met:

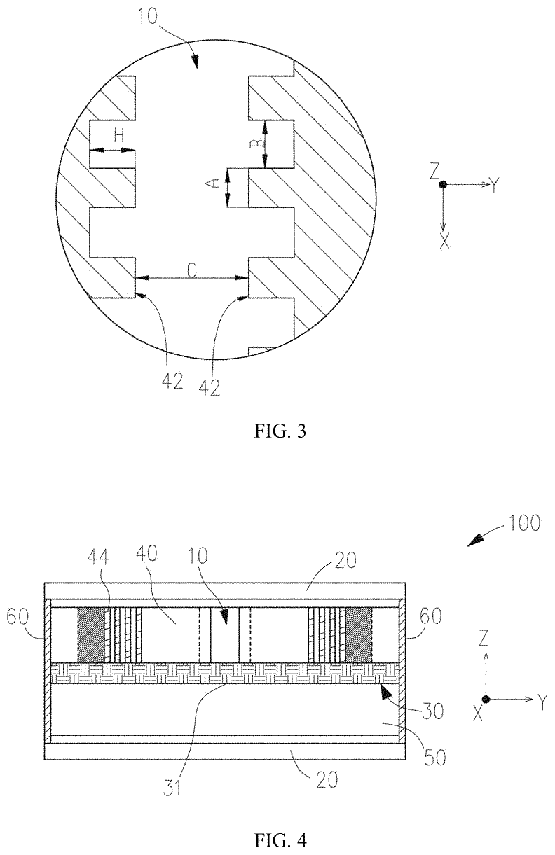

A+B=λ,

where A and B are sizes of two parts in one period of the optical grating respectively, as shown in FIG. 3, A is the width of a protruding part of the optical grating in the X-axis direction, B is the width of a slit of the optical grating in the X-axis direction, and λ is the laser wavelength. The interval of the optical gratings 42, i.e. the width C of the acceleration channel 10, and the height H of the optical grating can be further optimized to further improve the acceleration gradient.

In the embodiment, two Brewster windows 44 are formed in the first waveguide layer 40 and are used to screen out lasers having a polarization direction parallel to the X-axis direction. The two Brewster windows 44 are located in front of and behind the accelerating area in the Y-axis direction, that is respectively disposed on two sides of the accelerating area. In the embodiment, the Brewster windows 44 are formed by etching over a semiconductor material. In a specific implementation, two areas of semiconductor material inclined with respect to the Y-axis within the first waveguide layer 40 may be formed by continuing to grow on the semiconductor material of the active area. Then the two areas of semiconductor material are etched to form the Brewster windows 44.

If the Brewster angle is defined as θ, the inclination angle of the Brewster window 44 with respect to the Y-axis is θ (the included angle between the Brewster window 44 and the Y-axis in front of the Y-axis direction in FIG. 2) or π-θ (the included angle between the Brewster window 44 and the Y-axis in back of the Y-axis direction in FIG. 2), and the relationship between the Brewster angle θ and the vacuum refractive index n₂ and the semiconductor material refractive index n₁ is

$$t g θ = \frac{{n}_{2}}{{n}_{1}} .$$

Defining an equivalent width of the Brewster window 44 in the Y-axis direction as D, an equivalent width of the vacuum in the Brewster window 44 in the Y-axis direction as D′, an equivalent width of the medium in the Brewster window 44 in the Y-axis direction as d, and an equivalent width of the medium in the laser resonator in the Y-axis direction as L′, then L′=2*L1′+2*L2′+2*d, D=D′+d, a laser wavelength is λ, and then n₂C+n₂D′+n₁L′=mλ, where m is a positive integer.

Taking the semiconductor material employing InGaAsP as an example, which has a refractive index n₁=3.5 and a vacuum refractive index n₂=1, then the Brewster angle θ may be calculated, i.e. satisfying the following formula

$$tg θ = \frac{{n}_{2}}{{n}_{1}} , \\ θ = arc tg \frac{{n}_{2}}{{n}_{1}} = 15.94 ° ,$$

and then 15.94° and 164.16° are inclined angles required for etching.

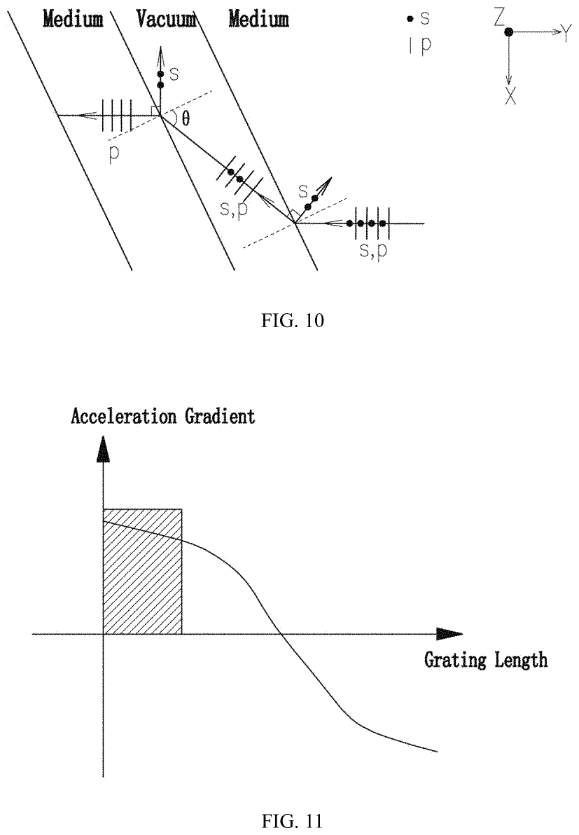

So configured, the active area generates lasers in all directions, the lasers which are not parallel to the Y-axis cannot be gain amplified, and the lasers which are parallel to the Y-axis pass through the Brewster windows to become linearly polarized lasers. According to the mechanism of stimulated radiation, since the lasers which passes through the Brewster window become linearly polarized lasers, when the lasers passes through the gain medium of the active area again, the generated lasers are linearly polarized lasers. The lasers thus travel back and forth in the resonator formed with the Brewster windows 44, and the lasers having the same polarization direction as that of the electron beam direction are screened out. As shown in FIG. 10, the lasers travel back and forth in the formed resonator and satisfy the Brewster angle condition every time when they enter the medium of the Brewster windows 44 from the vacuum, so that the polarized lights in s direction are reflected, and the reflected lights deviate from the central-axis light path, gradually attenuate, and cannot be gained. The single refracted lights still contain polarization in the s polarization direction, but the polarization component of s direction contained in the refracted lights is rapidly reduced after the refracted lights pass through the Brewster windows multiple times in a single round trip process. Finally, good p-direction polarized lights are achieved. As a result, high energy state electrons in the semiconductor active area are irradiated by linearly polarized lasers, and the lasers after gaining have the same polarization direction. Although the lasers still contains a small part of s polarization, the number thereof is greatly different from the p direction in an order of magnitude, so that the electron acceleration is not influenced, and the acceleration field and the electron movement direction can be the same, namely, the accelerated lasers are linearly polarized lasers.

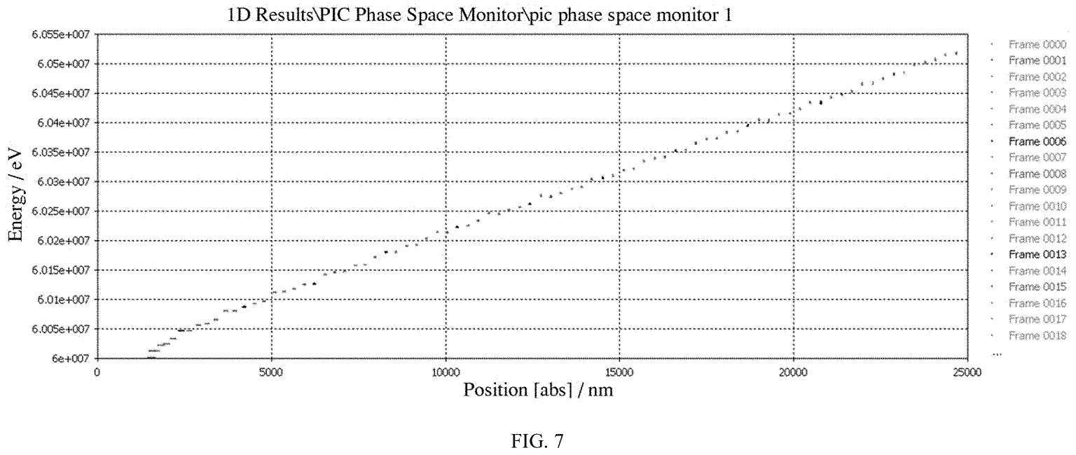

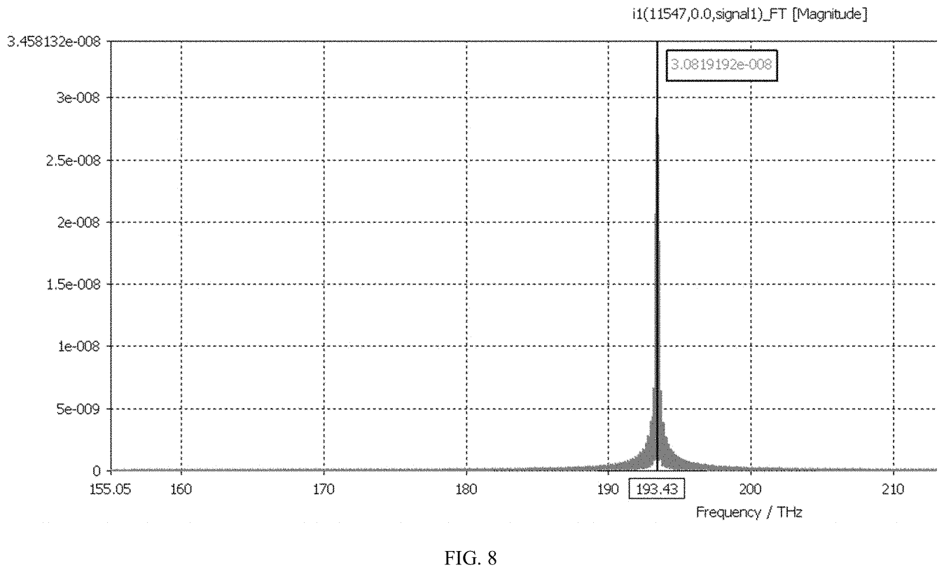

In a specific example, when InGaAsP is selected as the semiconductor material, and two optical gratings are formed by means of photolithography and wet etching, the corresponding laser wavelength λ is 1550 nm. A/B=1, C=0.35λ, H=0.9λ are set as initial conditions of iterative simulation, and then the light field distribution in the accelerating area is shown in FIG. 6. The result of electron acceleration can be obtained using electromagnetic field analysis software. By means of parameter scanning, the optimal acceleration effect can be obtained by modifying four optical grating size parameters of A, B, C, and H. The X-component of the electric field peak value distribution in the XY plane is shown in FIG. 6, the X-axis corresponds to the direction of electron travel and the Y-axis corresponds to the direction of laser travel. As can be seen from FIG. 6, the acceleration unit of this structure forms an accelerated electric field with a high gradient in the central area of the optical grating, and can accelerate the relativistic electron. FIG. 7 shows a simulation result of electron acceleration. The electron energy is 60 MeV at the entrance end and 60.53 MeV at the exit end, and the electron is accelerated in the accelerating area. FIG. 8 shows a Fourier transform of the field probe measurements, from which it can be seen that the frequency bandwidth of the acceleration field is narrow, and better accelerating effect can be achieved.

In summary, the electrodes 20, the active layer 30, the first waveguide layer 40, the second waveguide layer 50, the reflecting layer 60 and other possibly functional layers constitute a semiconductor laser apparatus. The active area realizes particle number inversion to achieve a basic laser gain condition when external excitation current is supplied, and the lasers generated by the active area are coupled into the waveguide layer with a certain connecting coefficient. According to the invention, the medium acceleration structure is innovatively combined in the resonator of the laser apparatus, that is, the electron accelerating area is directly located in the semiconductor laser apparatus, so that sturctures for forming an external complex light path are omitted, and the accelerator structure is small and exquisite. By arranging the Brewster windows, the lasers in the resonator reach good polarized lights with the same direction as that of the acceleration direction, and the linearly polarized characteristic of the light field is ensured.

In addition, the controller is used for controlling the excitation current supplied to the accelerating area, the threshold current can be used for effectively controlling the light field in the resonator, and the phase matching control of the electron beam and the light field can be realized. The excitation current can control the field building time of the laser acceleration field, and the short optical grating cascade manner is employed for acceleration so that the deceleration effect of the phase slip area can be effectively avoided (referring to FIG. 9), the high acceleration gradient of each section of acceleration segment is ensured, and the problem of phase slip is solved.

While in the above embodiment, InGaAsP is used for the semiconductor material, it will be understandably that semiconductor materials which may be employed by other laser apparatus may be employed in variant embodiments.

In the above-described embodiments, the acceleration unit has a cuboid shape as a whole appearance. It is understood that the acceleration unit may be variously changed in shape. For example, in other embodiments, the front end and the back end of the acceleration unit in the Y-axis direction may have an arc-shaped protrusion or a hemisphere shape. For another example, in other embodiments, the front end and the back end of the acceleration unit in the Z-axis direction may be ladder patterned or generally triangular or trapezoid-shaped.

In the embodiments described above, the Brewster windows are arranged symmetrically with respect to the acceleration channel. In other embodiments, the Brewster windows on both sides of the acceleration channel may have different equivalent widths in the Y-axis direction.

In the above-described embodiments, two optical gratings are arranged on both sides of the acceleration channel, and in other embodiments, only one optical grating may be arranged on only one side of the acceleration channel.

Compared with a traditional normal-temperature acceleration structure and a superconducting acceleration structure, the semiconductor laser accelerator provided by the invention has a higher acceleration gradient, so that the structure is smaller and more exquisite. Compared with the existing medium acceleration structure, the invention has advantages as follows: 1) the structure is simple, and the acceleration field is built in the semiconductor laser apparatus rather than the optical grating being irradiated by an external laser apparatus to form the acceleration field, namely the accelerating area is combined with the laser resonance area without needing a complex external optical system; 2) the light field is controlled by external excitation current, the phase matching control of the electron beam and the light field can be realized, and the problem of phase slip can be solved through cascade expansion; and 3) Brewster windows are set with a specific angle to ensure the linearly polarized characteristic of the light field.

While the invention has been described in terms of several exemplary embodiments, those skilled on the art will recognize that the invention can be practiced with modification within the spirit and scope of the appended claims. In addition, it is noted that, the Applicant's intent is to encompass equivalents of all claim elements, even if amended later during prosecution.

What is claimed is:

1. A semiconductor laser accelerator, comprising:
a plurality of laser acceleration units coupled in a cascade manner; and
a controller configured for controlling excitation current supplied to each laser acceleration unit;
wherein a space rectangular coordinate system xyz is defined, and each laser acceleration unit comprises:
an active layer, having an active area;
a first waveguide layer configured in front of the active layer in the Z-axis direction;
an electrode configured in front of the first waveguide layer in the Z-axis direction;
a second waveguide layer configured behind the active layer in the Z-axis direction;
another electrode configured behind the second waveguide layer in the Z-axis direction; and
two reflecting layers located in front of and behind the active layer, the first waveguide layer, and the second waveguide layer in a Y-axis direction;
wherein the active area is configured to generate laser when the electrodes are energized, and the active layer extends in parallel to a plane defined by X-axis and Y-axis;
wherein the first waveguide layer defines an acceleration channel extending along an X-axis direction, and one or two optical gratings configured on one or two sides of the acceleration channel to serve as an accelerating area;
wherein the controller realizes control and adjustment of a phase of an electromagnetic field in the accelerating area by adjusting triggering time of the excitation current;
wherein two Brewster windows for screening out lasers having a polarization direction parallel to the X-axis direction are formed in front of and behind the accelerating area in the Y-axis direction.

2. The semiconductor laser accelerator according to claim 1, wherein there are two optical gratings configured on both sides of the acceleration channel.

3. The semiconductor laser accelerator according to claim 2, wherein the two Brewster windows are formed by etching over a semiconductor material, a Brewster angle is defined as θ, an inclined angle of the Brewster window with respect to the Y-axis is θ or π-θ, and a relationship between the Brewster angle θ and a vacuum refractive index n₂ and a semiconductor material refractive index n₁ is
$$t g θ = \frac{{n}_{2}}{{n}_{1}} .$$

4. The semiconductor laser accelerator according to claim 3, wherein a width of the acceleration channel in the Y-axis direction is defined as C, an equivalent width of vacuum in the Brewster window in the Y-axis direction is D′, an equivalent width of a medium in a laser resonator in the Y-axis direction is L′, and a laser wavelength is λ, and then n₂C+n₂D′+n₁L′=mλ, where m is a positive integer.

5. The semiconductor laser accelerator according to claim 4, wherein the active area and the semiconductor material forming the Brewster window comprise InGaAsP semiconductor material.

6. A semiconductor laser acceleration unit, located in a space rectangular coordinate system XYZ, comprising:
an active layer, having an active area;
a first waveguide layer configured in front of the active layer in the Z-axis direction;
an electrode configured in front of the first waveguide layer in the Z-axis direction;
a second waveguide layer configured behind the active layer in the Z-axis direction;
another electrode configured behind the second waveguide layer in the Z-axis direction; and
two reflecting layers located in front of and behind the active layer, the first waveguide layer, and the second waveguide layer in a Y-axis direction;
wherein the active area is configured to generate lasers when the electrodes are energized, and the active layer extends in parallel to a plane defined by X-axis and Y-axis;
wherein the first waveguide layer defines an acceleration channel extending along an X-axis direction, and the first waveguide layer further comprises one or two optical gratings confiugred on one or two sides of the acceleration channel to serve as an accelerating area;
wherein the controller realizes control and adjustment of a phase of an electromagnetic field in the accelerating area by adjusting triggering time of the excitation current;
wherein two Brewster windows for screening out lasers having a polarization direction parallel to the X-axis direction are formed in front of and behind the accelerating area in the Y-axis direction.

7. The semiconductor laser acceleration unit according to claim 6, wherein there are two optical gratings configured on both sides of the acceleration channel.

8. The semiconductor laser acceleration unit according to claim 7, wherein the Brewster windows are formed by etching over a semiconductor material, a Brewster angle is defined as θ, an inclined angle of the Brewster window with respect to the Y-axis is θ or π-θ, and a relationship between the Brewster angle θ and a vacuum refractive index n₂ and a semiconductor material refractive index n₁ is
$$t g θ = \frac{{n}_{2}}{{n}_{1}} .$$

9. The semiconductor laser acceleration unit according to claim 8, wherein a width of the acceleration channel in the Y-axis direction is defined as C, an equivalent width of vacuum in each Brewster window in the Y-axis direction is D′, an equivalent width of a medium in a laser resonator in the Y-axis direction is L′, and a laser wavelength is λ, and then n₂C+n₂D′+n₁L′=mλ, where m is a positive integer.

10. The semiconductor laser acceleration unit according to claim 9, wherein the active area and the semiconductor material forming the Brewster window comprise InGaAsP semiconductor material.
